(19) United States
(12) Patent Application Publication
(10) Pub. No.: US 2019/0062520 A1
(43) Pub. Date: Feb. 28, 2019

(54) LIQUID CRYSTAL POLYMER ARTICLE FOR HIGH TEMPERATURE SEMICONDUCTOR PROCESS

(71) Applicant: IQLP, LLC, Woburn, MA (US)

(72) Inventors: Michael A. Zimmerman, No. Andover, MA (US); F. Michael Mahoney, Holliston, MA (US); William S. Scavuzzo, Newton Junction, NH (US)

(73) Assignee: IQLP LLC, Woburn, MA (US)

(21) Appl. No.: 15/777,848

(22) PCT Filed: Nov. 22, 2016
(86) PCT No.: PCT/US2016/063309

§ 371 Date: Nov. 15, 2018

Related U.S. Application Data
(60) Provisional application No. 62/259,320, filed on Nov. 24, 2015.

(51) Int. Cl. C08K 3/04; C09K 19/38; C09K 19/52; H01L 23/60

(52) U.S. Cl. CPC C08K 3/04; C09K 19/3809; C09K 19/52; C08K 2201/016; C08K 2201/005; C08K 2201/006; H01L 23/60

(57) ABSTRACT

A Front-Opening Unified Pod (FOUP), and more particularly an injection molded liquid crystal polymer article used in making the FOUP which both positive CTE value and shrinkage values and similar expansion and shrinkage of the article in both the MD and TD directions.

### CROSS-REFERENCE TO RELATED APPLICATION

This application claims the benefit of U.S. Provisional Application No. 62/259,320, filed Nov. 24, 2015, entitled “LCP PRODUCT FOR HIGH TEMPERATURE SEMI-CONDUCTOR PROCESSES.” The aforementioned application is hereby incorporated by reference.

### FIELD OF THE INVENTION

The present invention generally relates to a Front-Opening Unified Pod (FOUP), and more particularly to an injection molded liquid crystal polymer article used in making the FOUP having both a positive CTE and shrinkage value of the article, and are of similar values in both the MD and TD to prevent warpage.

### BACKGROUND OF THE INVENTION

Typically. Semi-conductor handling equipment, such as a Front-Opening Unified Pod (FOUP), have stringent performance requirements for application in semi-conductor wafer fabs, such as no or low material contamination levels, barrier resistance to oxygen and water vapor, specific levels of surface resistivity for electro-static discharge (ESD) capabilities, and high-temperature deformation resistance in wafer handling steps. In addition, fabrication, generally by injection-molding, of semi-conductor handling equipment, must exhibit high precision in isotropic shrinkage without warpage.

Liquid Crystal Polymer (LCP) materials have been evaluated in the past for use in semi-conductor handling equipment. Specifically, LCPs had been evaluated as an opportunity to increase the process temperature above 130° C. to as high a temperature as possible. A higher process temperature allows a hotter wafer to be placed in the FOUP, which increases productivity since less time is needed to cool the wafer.

LCP materials are inherently anisotropic with long, crystalline polymer chains aligning with material flow directions during molding or extrusion. For example, traditional LCP compounds are typically filled with either glass fiber or minerals, and the combination of molecular orientation and filler type results in very non-isotropic mechanical properties. Critical properties of interest are coefficient of thermal expansion and shrinkage in both the flow (MD) and Transverse(TD) directions. Typical LCPs have a CTE in the MD direction <5 ppm/C and the CTE in transverse direction is typically >20 ppm/C. Shrinkage is typically also very anisotropic. In flow direction shrinkage can be close to zero or negative, and shrinkage in TD is much higher and positive. Typical variations (MD verses TD) in shrinkage for glass filled LCPs, especially for large parts can cause for significant warpage.

Technical Needs for an LCP FOUP include:

No contamination of wafer fabrication process.

High bather properties for H₂O and O₂.

Low shrinkage and warpage: Positive CTE and Shrinkage in MD and TD which are equal or very close to being equal to make for minimum warpage.

Low ESD

High temperature deformation resistance:

Daily washing with no wear.

Thus there exists a need for a LCP compounded polymer which can used in a FOUP and which meets all of the required technical needs.

### SUMMARY OF THE INVENTION

According to one aspect of the present invention, an injection molded liquid crystal polymer article is provided that comprises: a thermotropic polyester; a filler, wherein the CTE value of the article in both the MD and TD directions are both positive, and within 12 ppm/C of each other, and the shrinkage values in both MD and TD are both positive and within 0.65% of each other.

In an aspect, the filler comprises 10-80 wt % of the article.

In an aspect, the filler comprises 20-30 wt % of the article.

In an aspect, the filler is graphite.

In an aspect, the graphite is in the form of crystalline flakes, amorphous fine flakes, lump graphite, or highly ordered pyrolytic graphite flakes.

In an aspect, the graphite filler comprises platelet shape particles.

In an aspect, the ratio of the length to width of the shaped particles is less than 5.

In an aspect, the filler is graphite and has a BET surface area less than 20 m²/g.

In an aspect, the electrical conductivity of the filler is greater than 1×10⁴ S/m and less than 1×10⁶ S/cm.

In an aspect, the filler is a graphite, and wherein the mean particle size of the graphite filler is in the range of 1-20 microns.

In an aspect, the particle size of the graphite is in the range of 1-6 microns.

In an aspect, the filler has impurity elemental levels of Aluminum, Calcium, Copper, Chromium, Cobalt, Nickel, Molybdenum, Silicon, Antimony, Arsenic, Lead, Titanium, Iron and Vanadium each less than 40 ppm, with the aggregate impurities level of all impurity elements being less than 75 ppm.

In an aspect, the thermotropic polyester is derived from hydroquinone(HQ), terephthalic acid(TA), 2,6-naphthalenedicarboxylic acid (NDA), or 4-hydrobenzoic acid (HBA).

In an aspect, the thermotropic polyester is derived from 4-hydrobenzoic acid (HBA).

In an aspect, the article has a nominal thickness of about 3 mm.

In an aspect, the ESD resistivity of the article is in the range of 10⁶-10¹⁰ Ohms/square.

In an aspect, the article has a heat deflection temperature greater than 260° C.

In an aspect, the article has a heat deflection temperature greater than 200° C.

In an aspect, the article has CTE values, which are between 10 and 35 ppm/C in both MD and TD directions.

In an aspect, the article has average shrinkage in both the MD and TD direction of less than 0.6%, and shrinkage in MD direction is positive.

In an aspect, the article has trace metal contamination levels which are no greater than 500 ppb in the leachate when analyzed via SEMI F48-0600 test.

In an aspect, a Front-Opening Unified Pod comprised of the article described in other aspects.

These and other features, advantages, and objects of the present invention will be further understood and appreciated by those skilled in the art by reference to the following specification, claims, and appended drawings.

### BRIEF DESCRIPTION OF THE DRAWINGS

In the drawings:

FIG. 1 is a plot of a sheer sweep curve as described in Example 3;

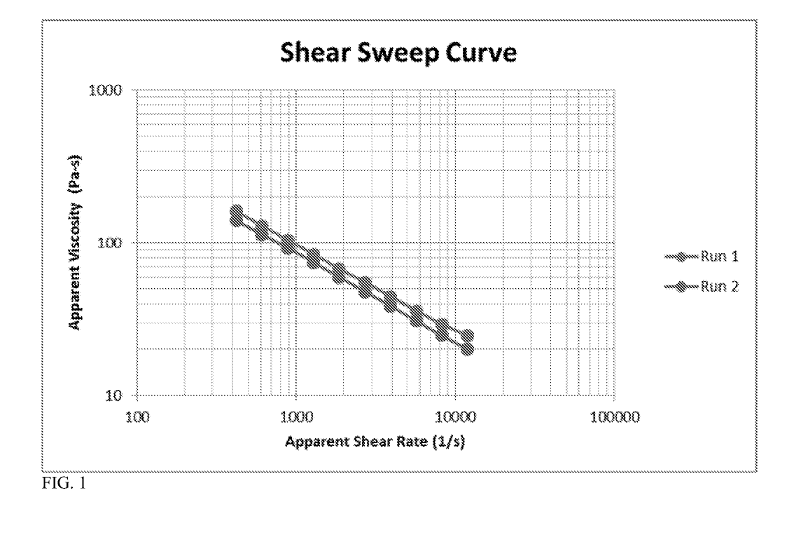

FIG. 2 is a scanning electron microscopy photo of the filler described in Example 4;

FIG. 3 is a scanning electron microscopy photo of the filler described in Example 4;

FIG. 4 is a scanning electron microscopy photo of the filler described in Example 4;

FIG. 5 is a scanning electron microscopy photo of the filler described in Example 4;

FIG. 6 is a scanning electron microscopy photo of the filler described in Example 4;

FIG. 7 is a plot of the shrinkage taken in the Machine Direction of the article described in Example 6;

FIG. 8 is a plot of the shrinkage taken in the Transverse Direction of the article described in Example 6;

FIG. 9 is a plot of the CTE taken in the Machine Direction of the article described in Example 7;

FIG. 10 is a plot of the CTE taken in the Transverse Direction of the article described in Example 7;

FIG. 11 is a plot of the shrinkage and CTE taken in the Machine Direction of the article described in Example 8;

FIG. 12 is a plot of the shrinkage and CTE taken in the Transverse Direction of the article described in Example 8.

### DETAILED DESCRIPTION OF THE PREFERRED EMBODIMENTS

Orientation is the alignment of polymer chains in a film in particular directions in the film. In general, there are three primary directions, two in the plane of the film and the third through the film. These directions are defined as the machine direction (MD), which is the direction that the resin moves through the machine and into the mold from start to finish. Next there is the transverse direction (TD) which is the direction perpendicular to the machine direction, and finally there is the thickness direction (ZD) which is perpendicular to the MD and TD directions.

The coefficient of thermal expansion describes how the size of an object changes with a change in temperature. Specifically, it measures the fractional change in size per degree change in temperature at a constant pressure. Several types of coefficients have been developed: volumetric, area, and linear. However, CTE shall mean for this specification the coefficient of linear thermal expansion which is the reversible increase in length of a material per unit length per degree change in temperature. Because CTE values are usually very small, it is common to express the expansion as ‘part per million’, i.e. ppm. This is typically ppm/° C. (for degrees Celsius) but expansion could also be expressed as ppm/° F. if the temperature range is measured in degrees Fahrenheit. The CTE can be positive, negative or zero, and these CTE values can vary in the MD and TD directions. It is preferred that CTE values be positive in both the MD and TD directions, and that both CTE (MD) and CTE (TD) be equal or similar to each other.

Molded and extruded parts can shrink or contract as they cool after leaving a mold, and shrinkage can vary in the MD and TD directions in anisotropic LCP materials. The measure of shrinkage is related to thermal expansion, and mold shrinkage is a percentage of the as-molded dimension. e.g. A mold shrinkage of 0.010 in./in. is equal to a 1%-dimensional change. Shrinkage can be positive, negative or zero, and can vary in the MD and TD directions. It is preferred that shrinkage values be positive in both the MD and TD directions, and that both Shrinkage (MD) and Shrinkage (TD) be equal or similar to each other. Determination of similarity is done by taking the difference in two values, with lower values being more preferable.

The liquid crystal polymer used is virgin and its monomers or repeat groups are derived from hydroquinone(HQ), terephthalic acid(TA), 2,6-naphthalenedicarboxylic acid (NDA), or 4-hydrobenzoic acid (HBA). By derived it is meant the repeat unit is not necessarily the monomer used but is derived from it or a derivative of that monomer in the polymerization reaction. The LCPs may be made by methods well known in the art, and Zenite 5000 supplied by Celenese is an example of a preferred LCP.

These LCPs may be mixed with other typical ingredients used in LCP compositions to form compositions comprising the LCP. Such materials include fillers. Particularly useful fillers are added, preferably in an amount of about 10 to about 80 parts by weight, more preferably about 20 to about 30 parts by weight per 100 parts by weight of LCP present.

Such compositions typically can be made by the well known technique of melt mixing the ingredients in typical thermoplastics melt processing equipment such as a kneader or single or twin screw extruders. By melt mixing is meant the mixing is done while the LCP is molten.

In an aspect, the filler is preferably a graphite, and can be a natural or synthetic graphite. The graphite can be crystalline and has a very high carbon content. The filler should have low contamination levels with respect to trace metals. If the filler has any elemental levels of Aluminum, Calcium, Copper, Chromium, Cobalt, Nickel, Molybdenum, Silicon, Antimony, Arsenic, Lead, Titanium, Iron and Vanadium—that they be at very low levels (less than 40 ppm), preferably less than 2 ppm, and most preferably less than 1 ppm. Aggregate impurities (all impurity elements) being preferably less than 75 ppm.

In an aspect, the shape of the filler material can affect the material properties of the LCP article. The shape can be a flake which is platelet shaped. Platelet is disk-shaped with the length and width being somewhat similar and much greater than the thickness. When the filler is a graphite, the graphite can be exfoliated or otherwise have a small thickness. The aspect ratio, herein defined as the ratio of the length and width is preferably small, and less than 5:1.

In an aspect, the compounded LCP article preferably does not leach impurities or otherwise act as a contaminant source. Nonvolatile trace inorganic impurities in bulk polymeric materials can be tested via standards such as SEMI F48-0600 (Reapproved 1214)—Test Method for Determining Trace Metals in Polymer Materials via ICP-MS, which can provide individual element leach concentrations as well as an aggregate amount.

Formulations which meet the low contamination levels, barrier resistance levels, surface resistivity target, while increasing the application temperature, as defined by the high temperature deformation resistance parameter, and allowing injection-molding of components with low, isotropic shrinkage and low warpage are described in the following examples:

### EXAMPLES

The compositions and processes described here, and ways to make and use them are illustrated in the following examples.

### Example 1

Formulation is created by mixing Z5000 (a neat LCP available from Celanese under the brand name Zenite)+30 wt. % KS 6-L graphite (available from Imerys Graphite & Carbon) using typical compounding methods. The graphite has the following characteristics:

Filler information: KS 6-L graphite (available from Imerys Graphite & Carbon)

Density=2.261 g/cc

Surface Area=18.7 m2/g (BET)

Low trace impurities, specifically Aluminum, Calcium, Copper, Chromium, Cobalt, Nickel, Molybdenum, Silicon, Antimony, Arsenic, Lead, Titanium, Iron and Vanadium impurities are at very low (less than 25 ppm), with the majority of the trace impurities being less than 2 ppm with many less than 1 ppm. The aggregate impurities (all impurity elements) being less than 50 ppm, with low values most preferred.

Particle size:

d10=1.6 μm

d50=3.5 μm

d90=6.6 μm

The formulation mixture was injection molded into an article.

### Example 2

The following physical characteristics are observed from the article created in Example 1:

EMod=7.0±0.2 GPa

Strain to failure=3.66±0.3%

Tensile strength=105±3 Mpa

### Example 3

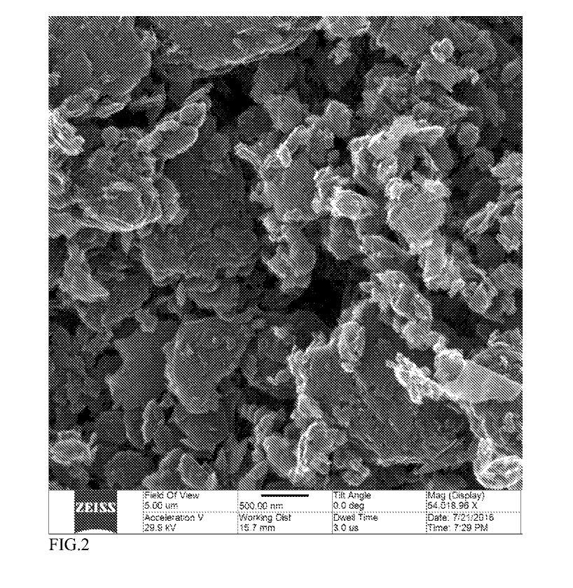

A shear sweep curve of the article created in Example 1 is created that describes the molding behavior by plotting the viscosity v. shear rate as shown in FIG. 2.

### Example 4

To investigate the characteristics of fillers useful in the formulation, multiple graphite fillers were assembled, and their physical characteristics detailed in Table 1.

TABLE 1

| | | | | | | | Bulk |
|---|---|---|---|---|---|---|---|
| | | | d10 | d50 | d90 | BET | Density |
| Name | Description | Company | (um) | (um) | (um) | (m²/g) | (g/cc) |
| Nano 99 | Natural Graphite | Asbury | | 2.2 | | 402 | |
| | Nano Platelets | | | | | | |
| Micro 850 | Natural Flake Graphite | Asbury | 2.3 | 4.2 | 8.1 | 16.7 | |
| KS-6L | Synthetic Graphite | Imerys Graphite | 1.6 | 3.5 | 6.6 | 18.7 | 0.07 |
| | | & Carbon | | | | | |
| KS-15 | Synthetic Graphite | Imerys Graphite | 2.7 | 7.3 | 16.0 | 12 | 0.10 |
| | | & Carbon | | | | | |
| KS-44 | Synthetic Graphite | Imerys Graphite | 4.7 | 18.6 | 46.4 | 9 | 0.19 |
| | | & Carbon | | | | | |

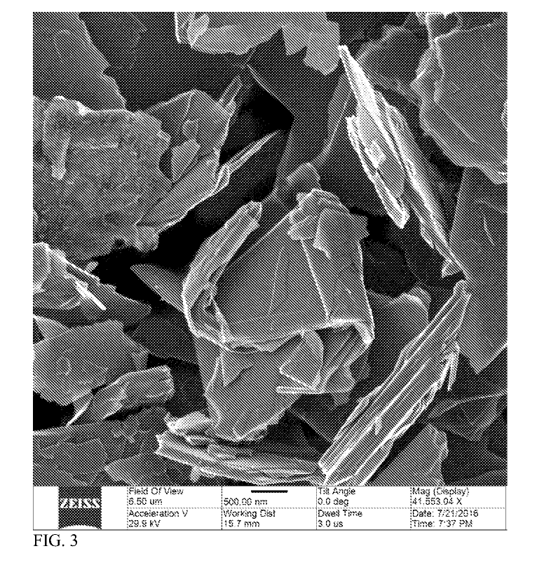

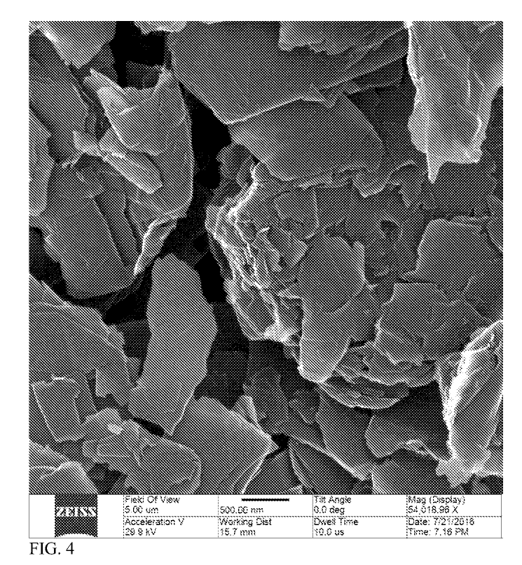

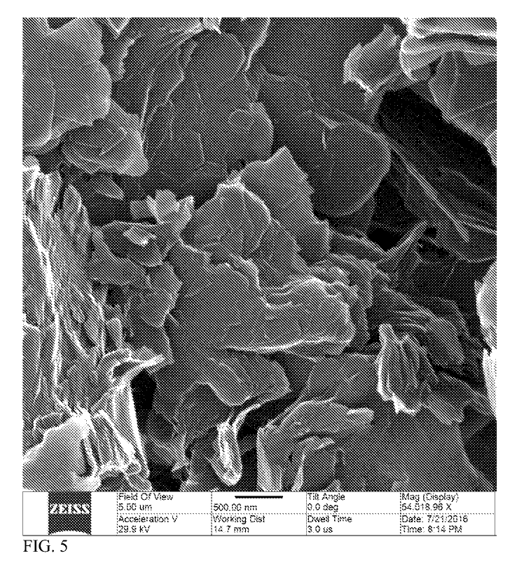

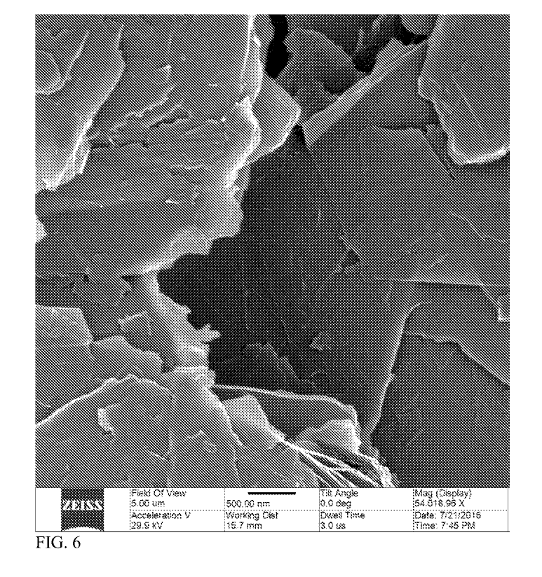

The graphites listed in Table 1 were assembled. Each of the graphites were photographed using scanning electron microscopy, see FIGS. 2-6. FIGS. 3-6 (respectively SEM of the materials shown in rows 2-5 in Table 1, with FIG. 3 representing Micro 850 etc.) show graphite particles in a flake like form. The thickness is far thinner than the width and length. The width and length being almost equal with little aspect ratio. However, the graphite in FIG. 2 (Nano 99) is highly faceted with seemingly higher surface area, which is supported by the BET measurement in Table 1.

Each of the graphites listed in Table 1 were used as fillers in a compounded polymer article. The fillers were used in three different weight percent loadings (20%, 25% and 30%) with the balance being Zenite 5000 Resin. Each polymer compound was molded into 3″×2″×0.062″ plaques.

### Example 6

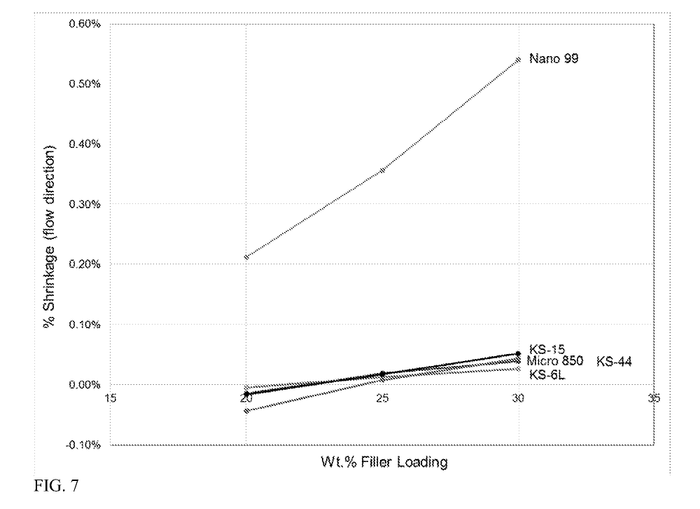

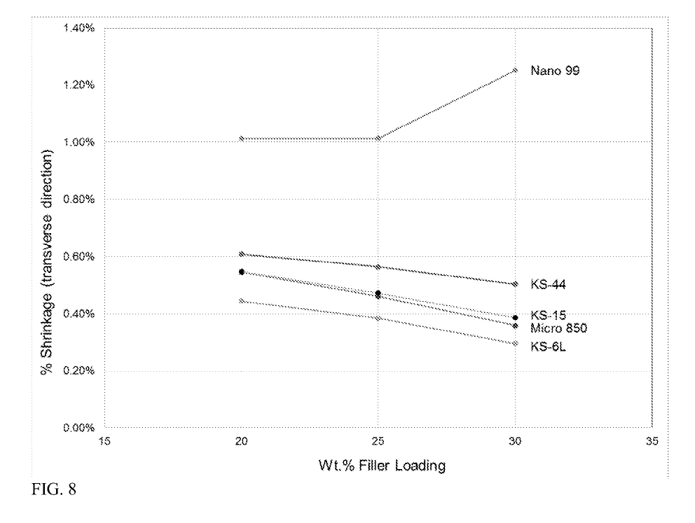

Plaques were molded according to Example 5, and measurements were conducted to determine shrinkage in both the machine direction and the transverse direction. The shrinkage data is presented in FIG. 7 and FIG. 8—MD and TD respectively. As can be seen, shrinkage is positive, significantly lower and does not vary with filler loading and is in the acceptable range for the low surface area graphites in that it is almost eliminated. Whereas for the high surface area graphite, the shrinkage varies with filler loading and is higher.

### Example 7

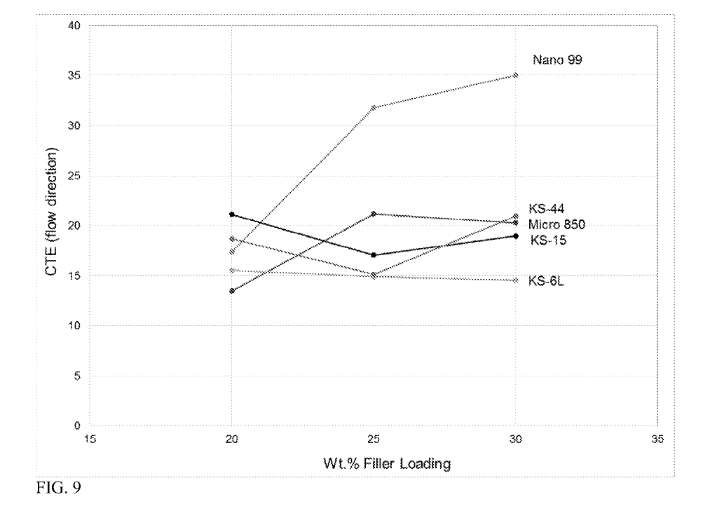

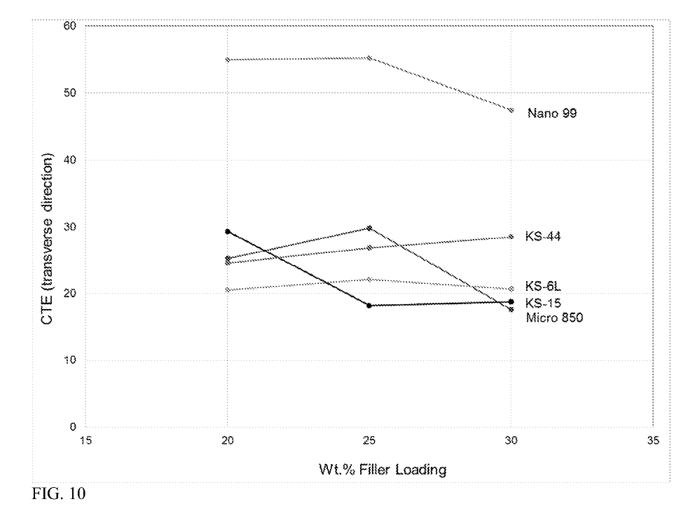

Plaques were molded according to Example 5, and then heated over the temperature range of 20-150 C. Measurements were conducted to determine thermal expansion in both the machine direction and the transverse direction. The CTE data is presented in FIG. 9 and FIG. 10—MD and TD respectively. As can be seen expansion is significantly lower, does not vary with filler loading and is in the acceptable range for the low surface area graphites. Whereas for the high surface area graphite, the shrinkage varies with filler loading and is generally higher.

### Example 8

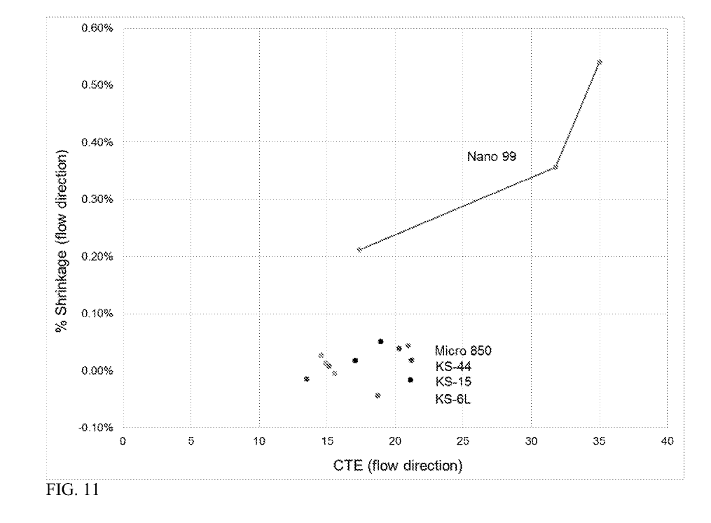

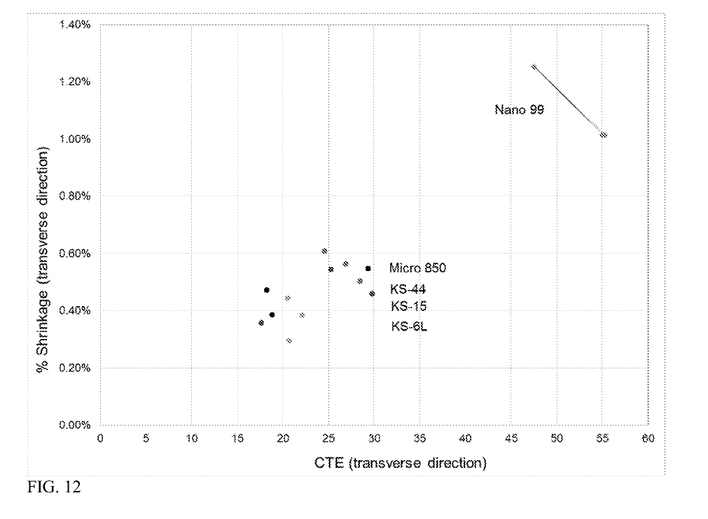

Data from Example 6 and 7 are plotted to illustrate the tightly bunched data in FIGS. 11 and 12. The low surface area fillers reduct the temperature sensitivity of the LCP composite while maintaining high barrier properties, statically dissipative properties, high temperature deformation resistance and abrasion resistance. The Tables 2 and 3 further document the CTE and Shrinkage data, and point out the respective differences between CTE and shrinkage in the MD and TD directions for each of the graphite fillers.

TABLE 2
Shrinkage data

| | | | | Shrinkage |
|---|---|---|---|---|
| Filler | % Filler | Shrinkage | Shrinkage | Difference |
| Nano 99 | | | | |
| Nano 99 | | | | |
| Nano 99 | | | | |
| Micro 850 | | | | |
| Micro 850 | | | | |
| Micro 850 | | | | |

TABLE 3
CTE data

| Filler | Difference |
|---|---|
| Nano 99 | |
| Nano 99 | |
| Nano 99 | |
| Micro 850 | |
| Micro 850 | |
| Micro 850 | |

### Example 9

The formulation described in Example 1 is used to mold parts of a FOUP, specifically the Shell, Door Housing, Door Cushion, and Wafer Supports, and each part performed as required. Specifically, each part met the aforementioned technical needs for an LCP FOUP. ESD was measured and found to be greater than 10⁸ Ohms/square. Superior bather properties were achieved. Aggregate contaminants (including: Aluminum Barium, Calcium, Chromium, Cobalt, Copper, Gallium, Iron, Lead, Lithium, Molybdenum, Magnesium, Manganese, Nickel, Potassium, Sodium, Strontium, Tin, Titanium, Zinc, Zirconium and other acid leachable trace metals) are less than 500 ppb in the leachate when analyzed via SEMI F48-0600 test and ICP-MS.

While the invention has been described in detail herein in accordance with certain preferred embodiments thereof, many modifications and changes therein may be affected by those skilled in the art without departing from the spirit of the invention. Accordingly, it is our intent to be limited only by the scope of the appending claims and not by way of the details and instrumentalities describing the embodiments shown herein.

What is claimed is:

1. An injection molded liquid crystal polymer article comprising:
a thermotropic polyester;
a filler,
wherein the CTE value of the article in both the MD and TD directions are both positive, and within 12 ppm/° C. of each other, and the shrinkage values in both MD and TD are both positive and within 0.65% of each other.

2. The article of claim 1, wherein the filler comprises 10-80 wt % of the article.

3. The article of claim 1, wherein the filler comprises 20-30 wt % of the article.

4. The article of claim 1 where the filler is graphite.

5. The article of claim 4, wherein the graphite is in the form of crystalline flakes, amorphous fine flakes, lump graphite, or highly ordered pyrolytic graphite flakes.

6. The article of claim 1, wherein the graphite filler comprises platelet shape particles.

7. The article of claim 6. wherein the ratio of the length to width of the shaped particles is less than 5.

8. The article of claim 1, wherein the filler is graphite and has a BET surface area less than 20 m²/g.

9. The article of claim 1, wherein the electrical conductivity of the filler is greater than 1×10⁴ S/m and less than 1×10⁶ S/cm.

10. The article of claim 1, wherein the filler is a graphite, and wherein the mean particle size of the graphite filler is in the range of 1-20 microns.

11. The article of claim 4, wherein the particle size of the graphite is in the range of 1-6 microns.

12. The article of claim 1, wherein the filler has impurity elemental levels of Aluminum, Calcium, Copper, Chromium, Cobalt, Nickel, Molybdenum, Silicon, Antimony, Arsenic, Lead, Titanium, Iron and Vanadium each less than 40 ppm, with the aggregate impurities level of all impurity elements being less than 75 ppm.

13. The article of claim 1 wherein the thermotropic polyester is derived from hydroquinone(HQ), terephthalic acid(TA), 2,6-naphthalenedicarboxylic acid (NDA), or 4-hydrobenzoic acid (HBA).

14. The article of claim 13, wherein the thermotropic polyester is derived from 4-hydrobenzoic acid (HBA).

15. The article of claim 15, wherein the article has a nominal thickness of about 3 mm.

16. The article of claim 1, wherein the ESD resistivity of the article is in the range of 10⁶-10¹⁰ Ohms/square.

17. The article of claim 1, wherein the article has a heat deflection temperature greater than 260° C.

18. The article of claim 1, wherein the article has a heat deflection temperature greater than 200° C.

19. The article of claim 1, wherein the article has CTE values, which are between 10 and 35 ppm/° C. in both MD and TD directions.

20. The article of claim 1, wherein the article has average shrinkage in both the MD and TD direction of less than 0.6%, and shrinkage in MD direction is positive.

21. The article of claim 1 where the article has trace metal contamination levels which are no greater than 500 ppb in the leachate when analyzed via SEMI F48-0600 test.

22. A Front-Opening Unified Pod comprised of a material described in claim 1.
